(19) United States
(12) Patent Application Publication
(10) Pub. No.: US 2012/0056611 A1
(43) Pub. Date: Mar. 8, 2012

(54) CONNECTION DETECTION CIRCUIT

(75) Inventors: MAO-SHUN HSI, Tu-Cheng (TW); YAU-SHI HWANG, Tu-Cheng (TW); CHUNG-CHIH CHOU, Tu-Cheng (TW); PO-NIEN WANG, Tu-Cheng (TW)

(73) Assignee: HON HAI PRECISION INDUSTRY CO., LTD., Tu-Cheng (TW)

(21) Appl. No.: 13/104,037

(22) Filed: May 10, 2011

(30) Foreign Application Priority Data
Sep. 6, 2010 (CN) 201010273223.7

(51) Int. Cl. G01R 19/00

(52) U.S. Cl. 324/76.11

(57) ABSTRACT

A connection detection circuit includes a first detection circuit and a second detection circuit. The first detection circuit includes a first comparator and a first detection pin connected to the first comparator. The first comparator is adapted to compare a first voltage level on the first detection pin with a first reference voltage. The second detection circuit includes a second detection pin. The second detection pin is adapted to connect to the first detection pin to vary the first voltage level on the first detection pin to switch an first transistor output when the connection of the first detection circuit and the second detection circuit is achieved.

### BACKGROUND

1. Technical Field

The present disclosure relates to a connection detection circuit.

2. Description of Related Art

When an external device is joined with an electronic device, an communication protocol between the electronic device and the external device is usually used to notify whether the external device is plugged into the electronic device. However, not all devices have this function. Furthermore, when the system is turned off or enters into the power saving mode, the method that confirms whether the external device is connected to the electronic device via telecommunication transmission is not applicable.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a circuit diagram of an embodiment of a connection detection circuit.

FIG. 2 is a circuit diagram of another embodiment of a connection detection circuit.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

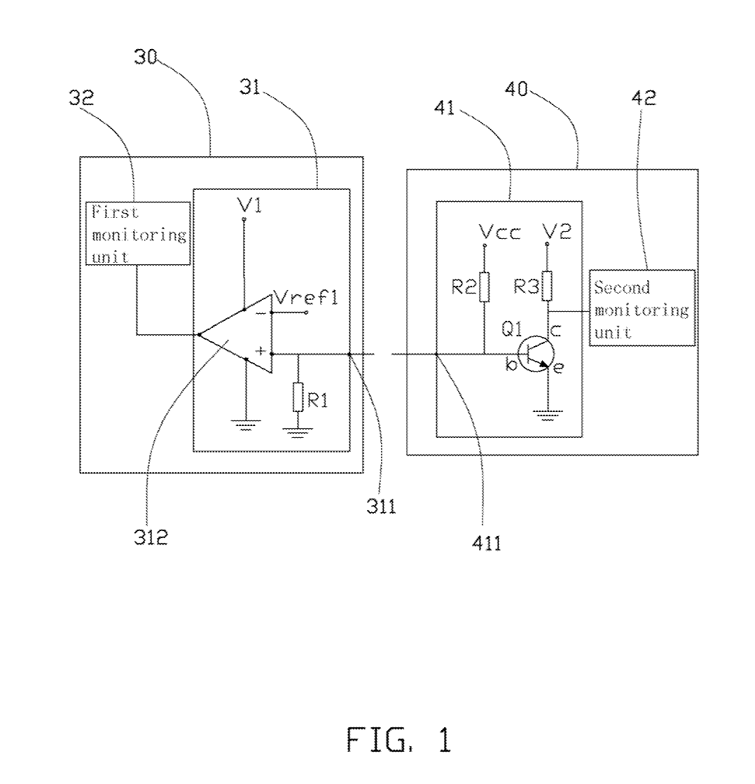

Referring to FIG. 1, a connection detection circuit in accordance with an embodiment of the present disclosure, is used to detect a connection of a first electronic device 30 and a second electronic device 40. The connection detection circuit includes a first detection circuit 31, a first monitoring unit 32, a second detection circuit 41, and a second monitoring unit 42. The first detection circuit 31 and the first monitoring unit 32 are set in the first electronic device 30. The second detection circuit 41 and the second monitoring unit 42 are set in the second electronic device 40.

The first detection circuit 31 includes a first detection pin 311, a first comparator 312, and a first resistor R1. The first comparator 312 includes a non-inverting input end, an inverting input end, an output end, a power end, and a ground end. The first detection pin 311 is connected to the first comparator non-inverting input end. A first reference voltage Vref1 is supplied to the first comparator inverting input end. The first comparator output end is connected to the first monitoring unit 32. The first comparator power end is connected to a first voltage V1. The first comparator ground end is connected to ground. The first resistor R1 is connected between the first detection pin 311 and ground.

The second detection circuit 41 includes a second detection pin 411, a second resistor R2, a third resistor R3, and a switch Q1. The second resistor R2 is connected between the second detection pin 411 and a direct current power Vcc. In one embodiment, the switch Q1 is an npn type transistor, whose threshold voltage is 0.7 volts. The switch Q1 includes a base b, a collector c, and an emitter e. The base b is connected to the second detection pin 411. The collector c is connected to a second voltage V2 via the third resistor R3. The emitter e is connected to ground. The collector c is further connected to the second monitoring unit 42.

In the above embodiment, the first reference voltage Vref1 is 0.3 volts. The direct current power Vcc is 5 volts. A resistance of the first resistor R1 is 10000 ohms. A resistance of the second resistor R2 is 100000 ohms.

When the second electronic device 40 is not connected to the first electronic device 30, the first detection pin 311 is in low level. A voltage on the first comparator non-inverting input end is lower than that of the first comparator inverting input end. The first comparator output end outputs a low level first indication signal to the first monitoring unit 32. The first monitoring unit 32 receives the low level first indication signal to recognize that the second electronic device 40 is not connected to the first electronic device 30. Simultaneously, the second detection pin 411 is set to be high level because of the direct current power Vcc. The switch Q1 is turned on. The switch collector c is connected to ground via the switch Q1. Therefore, the second monitoring unit 42 receives a low level second indication signal to recognize that the first electronic device 30 is not connected to the second electronic device 40.

When the second electronic device 40 is connected to the first electronic device 30, the first detection pin 311 is connected to the second detection pin 411. The direct current power Vcc is connected to ground via the second resistor R2 and the first resistor R1. A voltage on the first detection pin 311 is equal to Vcc*R1/(R1+R2)=0.45 volts, which is higher than the first reference voltage Vref1. The first comparator output end outputs a high level first indication signal to the first monitoring unit 32. The first monitoring unit 32 receives the high level first indication signal to recognize that the second electronic device 40 is connected to the first electronic device 30. Simultaneously, a voltage on the switch base b is 0.45 volts, which is lower than the switch threshold voltage. The switch Q1 is turned off. A voltage on the collector of the switch Q1 is high. Therefore, the second monitoring unit 42 receives a high level second indication signal to recognize that the first electronic device 30 is connected to the second electronic device 40.

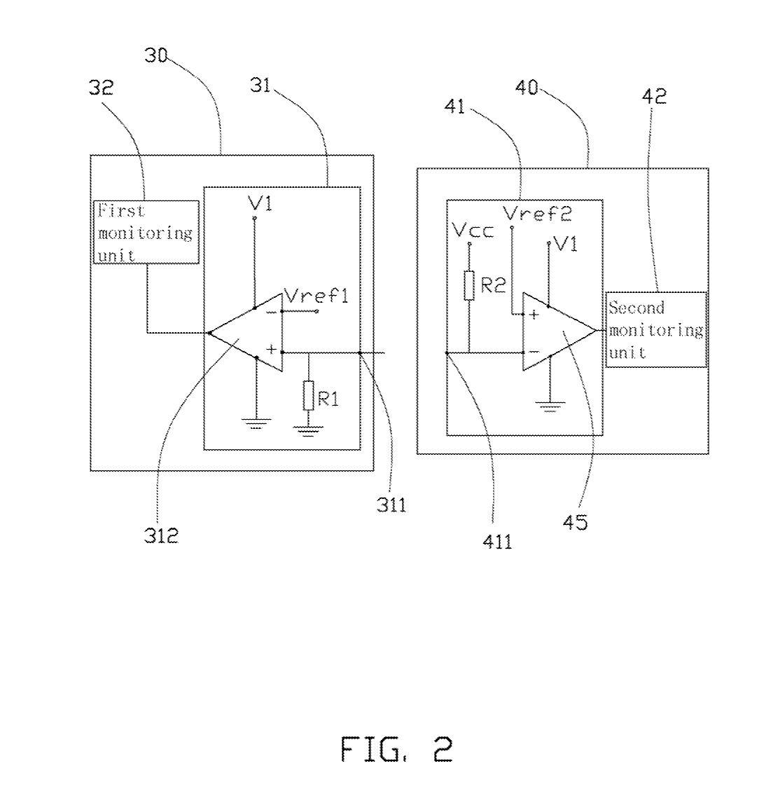

Referring to FIG. 2, a connection detection circuit in accordance with another embodiment of the present disclosure is shown. In this embodiment, a second comparator 45 replaces the switch Q1 of the above embodiment. The second comparator 45 includes a non-inverting input end, an inverting input end, and an output end. The second comparator non-inverting input end is connected to a second reference voltage Vref2, which is 0.6 volts. The second comparator inverting input end is connected to the second detection pin 411. The second comparator output end is connected to the second monitoring unit 42.

When the second electronic device 40 is not connected to the first electronic device 30, a voltage on the second comparator inverting input end is higher than that of the second comparator non-inverting input end. The second comparator output end outputs a low level signal to the second monitoring unit 42 to indicate that the first electronic device 30 is not connected to the second electronic device 40.

When the second electronic device 40 is connected to the first electronic device 30, the first detection pin 311 is connected to the second detection pin 411. The direct current power Vcc is connected to ground via the second resistor R2 and the first resistor R1. A voltage on the second detection pin 411 is equal to Vcc*R1/(R1+R2)=0.45 volts, which is lower than the second reference voltage Vref2. The second comparator output end outputs a high level signal to the second monitoring unit 42 to indicate that the first electronic device 30 is connected to the second electronic device 40.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed. It is also to be understood that the above description and the claims drawn to a method may include some indication in reference to certain steps. However, the indication used is only to be viewed for identification purposes and not as a suggestion as to an order for the steps.

What is claimed is:

1. A connection detection circuit, comprising:
a first detection circuit comprising a first comparator and a first detection pin connected to the first comparator, the first comparator adapted to compare a first voltage level on the first detection pin with a first reference voltage; and
a second detection circuit comprising a second detection pin; wherein the second detection pin is adapted to connect to the first detection pin to change the first voltage level on the first detection pin to vary a first comparator output when an connection of the first detection circuit and the second detection circuit is achieved.

2. The connection detection circuit of claim 1, wherein the first comparator comprises a first non-inverting input end and a first inverting input end, the first detection pin is connected to the first non-inverting input end, and the first reference voltage is connected to the first inverting input end.

3. The connection detection circuit of claim 2, wherein the first detection pin is connected to ground via a first resistor to have the first voltage level on the first detection pin being lower than the first reference voltage, the second detection pin is connected to a direct current power via a second resistor, the second detection pin is adapted to connect to the first detection pin to have the first voltage level on the first detection pin being higher than the first reference voltage.

4. The connection detection circuit of claim 1, wherein the second detection circuit is connected to a switch, the switch is adapted to send a first indication signal when the connection of the first detection circuit and the second detection circuit is achieved, and is adapted to send a second indication signal when there is no connection between the first detection circuit and the second detection circuit.

5. The connection detection circuit of claim 4, wherein the switch is a NPN type transistor, the switch comprises a base, a collector, and an emitter, the base is connected to the second detection pin, the collector is connected to the a second voltage, the emitter is connected to ground; the switch is adapted to be turned on to have the collector to send a low level voltage signal when there is no connection between the first detection circuit and the second detection circuit, and adapted to be turned off to have the collector to send a high level voltage signal when there is a connection between the first detection circuit and the second detection circuit.

6. The connection detection circuit of claim 1, wherein the second detection pin is connected to a second comparator, the second comparator is adapted to compare a second voltage level on the second detection pin with a second reference voltage, and the second voltage level on the second detection pin is adapted to be changed to alter an second comparator output when there is a connection between the first detection circuit and the second detection circuit.

7. The connection detection circuit of claim 6, wherein the second comparator comprises a second inverting input end and a second non-inverting input end, the second detection pin is connected to the second inverting input end, and the second reference voltage is connected to the second non-inverting input end.

8. The connection detection circuit of claim 7, wherein the first detection pin is connected to ground via a first resistor, the second detection pin is connected to a direct current power via a second resistor to have the second voltage level on the second detection pin being higher than the second reference voltage, and the first detection pin is adapted to connect to the second detection pin to have the second voltage level on the second detection pin being lower than the second reference voltage.

9. A connection detection circuit comprising:
a first detection circuit comprising a first detection pin; and
a second detection circuit comprising a second detection pin and a switch connected to the second detection pin, the switch adapted to output a first indication signal when a connection of the first detection circuit and the second detection circuit is achieved, and adapted to send a second indication signal when there is no connection between the first detection circuit and the second detection circuit.

10. The connection detection circuit of claim 9, wherein the switch is a NPN type transistor, the switch comprises a base, a collector, and an emitter, the base is connected to the second detection pin, the collector is connected to the a second voltage, the emitter is connected to ground; the switch is adapted to be turned on to have the collector to send a low level voltage signal when there is no connection between the first detection circuit and the second detection circuit, and adapted to be turned off to have the collector send a high level voltage signal when there is a connection between the first detection circuit and the second detection circuit.

11. The connection detection circuit of claim 9, wherein the first detection pin is connected to a first comparator, the first comparator is adapted to compare a first voltage level on the first detection pin with a first reference voltage, and the first voltage level on the first detection pin is configured to be changed to vary a first comparator output when the connection of the first detection circuit and the second detection circuit is achieved.

12. The connection detection circuit of claim 11, wherein the first comparator includes a first non-inverting input end and a first inverting input end, the first detection pin is connected to the first non-inverting input end, and the first reference voltage is connected to the first inverting input end.

13. The connection detection circuit of claim 12, wherein the first detection pin is connected to ground via a first resistor to have the first voltage level on the first detection pin being lower than the first reference voltage, the second detection pin is connected to a direct current power via a second resistor, the second detection pin is adapted to connect to the first detection pin to have the first voltage level on the first detection pin being higher than the first reference voltage.
